(19) United States
(12) Patent Application Publication
(10) Pub. No.: US 2003/0215752 A1
(43) Pub. Date: Nov. 20, 2003

(54) Device manufacturing method

(75) Inventors: Yoshiharu Ono, Hyogo (JP); Takayuki Saito, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/303,734

(22) Filed: Nov. 26, 2002

(30) Foreign Application Priority Data
May 14, 2002 (JP) 2002-138320(P)

(51) Int. Cl. G03F 7/16; G03F 7/20

(52) U.S. Cl. 430/312; 430/315

(57) ABSTRACT

An insulating film is formed on a semiconductor substrate and a photoresist film is formed on the insulating film. The photoresist film is patterned so that a first mask pattern including a thin film portion is formed. A photoresist film is formed over the first mask pattern so as to cover the thin film portion. A second mask pattern is formed by patterning this photoresist film and, at the same time, a portion of the photoresist film is left on the thin film portion. The insulating film is processed using the first and second mask patterns.

### BACKGROUND OF THE INVENTION

1. Field of the Invention

The present invention relates to a device manufacturing method, and more particularly to a method for forming a microscopic pattern using a mask film such as photoresist.

2. Description of the Background Art

Some semiconductor devices have, for example, a semiconductor substrate, an element on the semiconductor substrate, an insulating film for covering the element, a contact hole provided in the insulating film and an upper layer wire electrically connected to the above described element via this contact hole.

In order to manufacture such a semiconductor device, an element may be formed on a semiconductor substrate, an insulating film may be formed so as to cover the element, a contact hole may be formed in the insulating film, a conductive film may be filled in into the contact hole and an upper layer wire may be formed over the insulating film so as to be electrically connected to this conductive film.

However, as the miniaturization of semiconductor devices has progressed, the distance between holes has become smaller and, at the same time, the following problem concerning the hole creation process has occurred.

An example of a conventional hole formation process is shown in FIGS. 11A, 11B and FIGS. 12A, 12B. First, an element (not shown) is formed on a main surface of a semiconductor substrate 1, and an insulating film 2 is formed so as to cover the element. A photoresist film 3 is applied to this insulating film 2 and photoresist film 3 is exposed using a predetermined mask and, after that, is developed so that a hole pattern 4 is formed in photoresist film 3, as shown in FIGS. 11A and 11B.

At this time, in the case that the distance between holes is small, the amount of film remaining of photoresist film 3 is insufficient between patterned holes 4, as shown in FIGS. 11A and 11B, causing a problem wherein a thin film portion 3a is formed or wherein patterned holes 4 are connected. Such a phenomenon occurs in the case that hole pattern 4, having dimensions and a pitch close to the resolution limit, is utilized wherein such dimensions and pitch vary depending on the wavelength of the light utilized for exposure.

In the case that insulating film 2 is etched using photoresist film 3, having thin film portion 3a as described above, as a mask, insulating film 2 is etched between contact holes 6 so as to form a thin film portion 2a, as shown in FIGS. 12A and 12B. Therefore, adjacent contact holes become connected to each other causing a problem wherein conductive films become connected to each other in the case that the conductive films are formed within these contact holes 6.

In addition, in many cases a half-tone phase shift mask is utilized in the hole formation process. Such a mask achieves an increase in resolution by allowing light to illuminate a non-exposed portion making use of a constant transmittance (for example, 3% or 6%) and by changing the phase by 180 degrees between this portion and a patterned portion.

However, when the above described half-tone phase shift mask is utilized in the case that patterned holes 4 are densely concentrated, as shown in FIGS. 13A and 13B, recesses 3b, referred to as dimples or side lobes, are generated inside regions wherein patterned holes 4 are densely concentrated or in the vicinity of patterned holes 4 having large opening areas. The remaining film of photoresist film 3 becomes insufficient in such a portion wherein a recess 3b is formed.

Here, the hole size, the hole pitch and the like for the generation of recesses 3b vary depending on the wavelength of the light utilized for exposure. In addition, the dimensions of recesses 3b are dependent on the exposure energy as well as the amount of defocus and are not dependent on the film thickness of photoresist film 3.

In the case that photoresist film 3, having recesses 3b as described above, is used as a mask so as to etch insulating film 2, insulating film 2 is etched between contact holes 6 so as to form recesses 6a, as shown in FIGS. 14A and 14B. Problems such as the occurrence of surface steps, the occurrence of unnecessary capacitors and short-circuiting between adjacent contact holes may be caused due to the existence of such recesses 6a.

Problems caused by an insufficient amount of remaining film of photoresist film 3, as described above, can be handled by increasing the film thickness of photoresist film 3. In the case that the film thickness of photoresist film 3 is increased; however, a problem arises wherein the resolution is lowered.

### SUMMARY OF THE INVENTION

The present invention is made to solve the above described problems and an object thereof is to provide a device manufacturing method wherein the thickness of thin film portions in a mask film is increased, thereby the mask film is allowed to function effectively.

A device manufacturing method according to the present invention includes the following steps, respectively. A first mask film is formed on an underlying portion. A first mask pattern including a thin film portion is formed by patterning the first mask film. A second mask film is formed over the first mask pattern so as to cover the thin film portion. A second mask pattern is formed by patterning the second mask film and a portion of the second mask film is left on the thin film portion. The underlying portion is processed using the first and second mask patterns. Here, the “underlying portion” indicates a portion of a semiconductor device that is, for example, etched using a mask or to which impurities are implanted, such as a conductive film, a semiconductor film or an insulating film formed on a semiconductor substrate or a semiconductor substrate.

As described above, a portion of the second mask film is left on the thin film portion of the first mask pattern, thereby the thickness of the thin film portion can be increased. Thereby, in the case that the underlying portion is etched using the first and second mask patterns, for example, the loss of the thin film portion can be avoided so that the underlying portion of a desired form can be obtained.

The above described step of patterning of the second mask film may include the step of forming the second mask pattern so that the second mask pattern becomes a pattern of the same form as the first mask pattern. For example, the first and second mask films may be patterned under substantially the same conditions or may be patterned using the same parameters. In the case that the first and second mask films are photoresist films, the second mask pattern may be formed using the same photomask as the photomask for the formation of the first mask pattern.

The step of the patterning of the second mask film may include the step of the patterning of the second mask film such that the second mask film is left on only the thin film portion of the first mask pattern. In this case, it is preferable for the first mask film to be a positive-type photoresist film and for the second mask film to be a negative-type photoresist film.

In addition, it is preferable to form a hardened layer on the surface of the first mask pattern after the above described first mask film is patterned. This hardened layer is typically formed by hardening the surface of the first mask pattern.

The above described underlying portion includes at least one of a semiconductor substrate and a film formed on a semiconductor substrate and, in the manufacturing method for a semiconductor device of the present invention, at least one of the above described semiconductor substrate and film is etched using a mask pattern, formed utilizing the above described mask pattern formation method, as a mask.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a plan view showing a first step of a manufacturing process for a semiconductor device using a device manufacturing method (mask pattern formation method) according to a first embodiment of the present invention, and FIG. 1B is a cross sectional view taken along a line Ib-Ib of FIG. 1A;

FIG. 2A is a plan view showing a second step of the manufacturing process for a semiconductor device using the mask pattern formation method according to the first embodiment of the present invention, and FIG. 2B is a cross sectional view taken along a line IIb-IIb of FIG. 2A;

FIG. 3A is a plan view showing a third step of the manufacturing process for a semiconductor device using the mask pattern formation method according to the first embodiment of the present invention, and FIG. 3B is a cross sectional view taken along a line IIIb-IIIb of FIG. 3A;

FIG. 4A is a plan view showing a fourth step of the manufacturing process for a semiconductor device using the mask pattern formation method according to the first embodiment of the present invention, and FIG. 4B is a cross sectional view taken along a line IVb-IVb of FIG. 4A;

FIG. 5A is a plan view showing a characteristic mask pattern formation step according to a second embodiment of the present invention, and FIG. 5B is a cross sectional view taken along a line Vb-Vb of FIG. 5A;

FIG. 6A is a plan view showing a characteristic mask pattern formation step according to a third embodiment of the present invention, and FIG. 6B is a cross sectional view taken along a line VIb-VIb of FIG. 6A;

FIG. 7A is a plan view showing the first step of a manufacturing process for a semiconductor device using a mask pattern formation method according to a fourth embodiment of the present invention, and FIG. 7B is a cross sectional view taken along a line VIIb-VIIb of FIG. 7A;

FIG. 8A is a plan view showing the second step of the manufacturing process for a semiconductor device using the mask pattern formation method according to the fourth embodiment of the present invention, and FIG. 8B is a cross sectional view taken along a line VIIIb-VIIIb of FIG. 8A;

FIG. 9A is a plan view showing the third step of the manufacturing process for a semiconductor device using the mask pattern formation method according to the fourth embodiment of the present invention, and FIG. 9B is a cross sectional view taken along a line IXb-IXb of FIG. 9A;

FIG. 10A is a plan view showing the fourth step of the manufacturing process for a semiconductor device using the mask pattern formation method according to the fourth embodiment of the present invention, and FIG. 10B is a cross sectional view taken along a line Xb-Xb of FIG. 10A;

FIG. 11A is a plan view showing the first step of a manufacturing process for a semiconductor device using a mask pattern formation method according to a prior art, and FIG. 11B is a cross sectional view taken along a line XIb-XIb of FIG. 11A;

FIG. 12A is a plan view showing the second step of the manufacturing process for a semiconductor device using the mask pattern formation method according to the prior art, and FIG. 12B is a cross sectional view taken along a line XIIb-XIIb of FIG. 12A;

FIG. 13A is a plan view showing the first step of another example of a manufacturing process for a semiconductor device using a mask pattern formation method according to a prior art, and FIG. 13B is a cross sectional view taken along a line XIIIb-XIIIb of FIG. 13A; and

FIG. 14A is a plan view showing the second step of the above example of the manufacturing process for a semiconductor device using the mask pattern formation method according to the prior art, and FIG. 14B is a cross sectional view taken along a line XIVb-XIVb of FIG. 14A.

### DESCRIPTION OF THE PREFERRED EMBODIMENTS

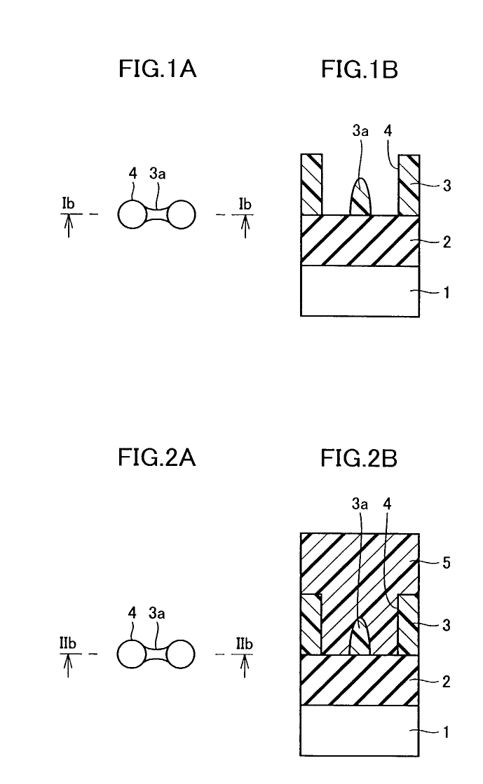

In the following, embodiments of the present invention will be described in reference to FIGS. 1 to 10.

(First Embodiment)

FIGS. 1A and 1B to FIGS. 4A and 4B are plan views and cross sectional views showing the respective manufacturing steps for a semiconductor device using a device manufacturing method (mask pattern formation method) according to the first embodiment of the present invention.

First, a variety of elements (not shown) such as MOS (Metal Oxide Semiconductor) transistors are formed on the main surface of a semiconductor substrate 1. After that, as shown in FIGS. 1A and 1B, an insulating film 2 is formed on semiconductor substrate 1 by means of a CVD (Chemical Vapor Deposition) method or the like. In the first embodiment, insulating film 2 becomes an underlying portion. A silicon oxide film or the like that can be utilized as an interlayer insulating film can be cited as insulating film 2.

Here, the present invention is applicable to the process of a film other than an insulating film, such as a conductive film or a semiconductor film, as long as that is a film formed on semiconductor substrate 1. In addition, the present invention is applicable in the case that a trench is formed in semiconductor substrate 1 or in the case that an impurity is implanted in semiconductor substrate 1.

A photoresist, which is a photosensitive material, is applied to insulating film 2 so as to form a photoresist film (first mask film) 3. Photoresist film 3 is exposed using a predetermined photomask (not shown). Thereby, photoresist film 3 can be exposed in accordance with a predetermined pattern formed in the photomask.

After that, photoresist film 3 is patterned by carrying out a developing process so as to form a hole pattern 4 in photoresist film 3, as shown in FIGS. 1A and 1B. Thereby, a photoresist pattern (first mask pattern) can be formed.

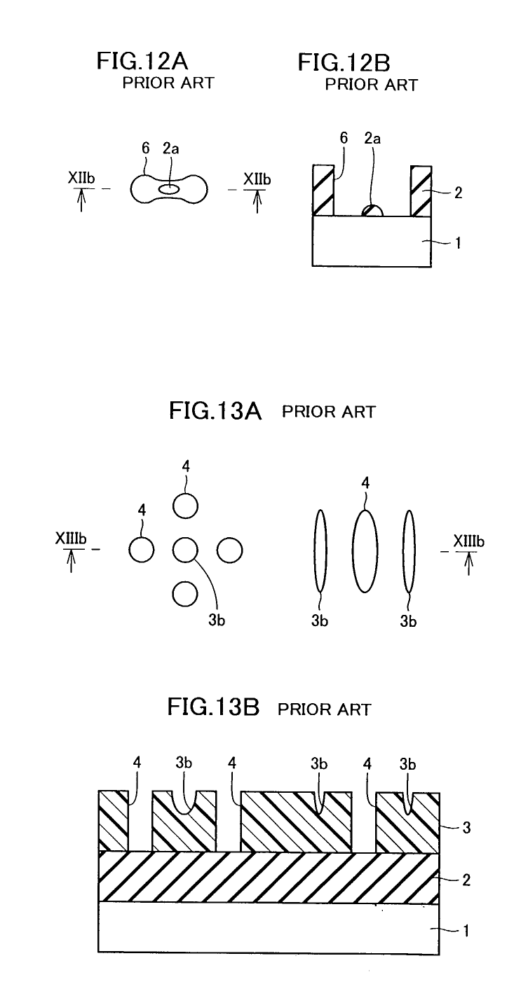

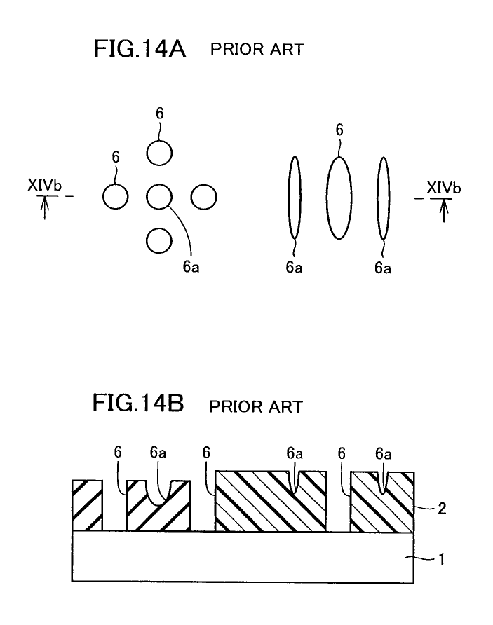

At this time, in the case that the intervals between patterned holes 4 are small, the film thickness of photoresist film 3 that remains between patterned holes 4 decreases so as to form a thin film portion 3a between patterned holes 4, as shown in FIGS. 1A and 1B. When insulating film 2 is etched using a mask pattern having such a thin film portion 3a, a problem occurs, as shown in FIG. 12.

Therefore, the same photomechanical (photolithography) process as described above is again carried out and a photoresist is supplied to thin film portion 3a so as to increase the thickness of thin film portion 3a. That is to say, a photoresist is applied so as to cover a photoresist film 3 that has been patterned so as to form a photoresist film (second mask film) 5, as shown in FIGS. 2A and 2B. Though it is preferable for the thickness of photoresist film 5 to not be less than the thickness of photoresist film 3, photoresist film 5 may have a thickness less than the thickness of photoresist film 3 as long as photoresist film 5 is left at a desired thickness on top of thin film portion 3a.

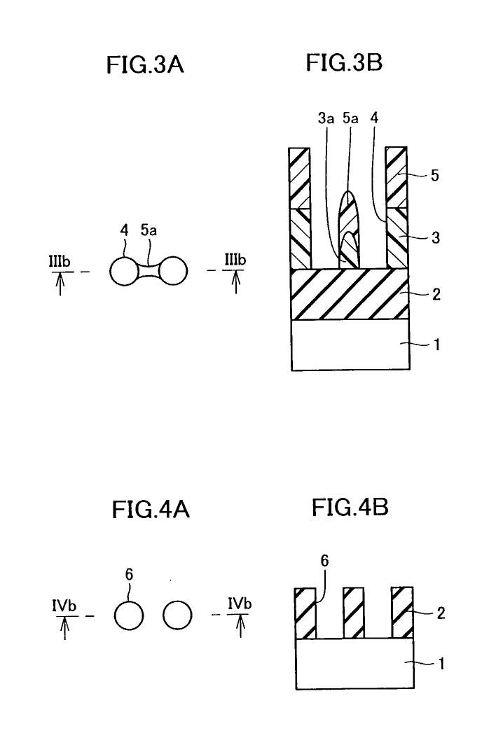

Next, the same photomask as in the case of photoresist film 3 is used so as to expose photoresist film 5. After that, photoresist film 5 is patterned by carrying out a developing process so as to form hole pattern 4 in photoresist film 5, as shown in FIGS. 3A and 3B.

Thereby, a photoresist pattern (second mask pattern) according to photoresist film 5 having substantially the same form as the photoresist pattern according to photoresist 3 can be formed on top of this pattern according to photoresist 3. Accordingly, the entirety of the photoresist pattern, including the thin film portion, becomes a thick film in the present embodiment.

At this time, a thin film portion 5a of photoresist film 5 is formed on top of thin film portion 3a resulting in an increase in the thickness of thin film portion 3a. For example, the thickness of thin film portion 3a can be increased to be approximately doubled. Though the total film thickness of thin film portion 3a and thin film portion 5a becomes a thickness that is no less than the thickness of photoresist film 3 in the example shown in FIG. 3, the above described total film may have a thickness that is not greater than the thickness of photoresist film 3 as long as it is not eliminated when the film thickness of thin film portions 3a and 5b is reduced in the below described etching process.

Next, the above described photoresist pattern according to photoresist film 3 and the photoresist pattern according to photoresist film 5 are used as a mask so as to etch insulating film 2 and contact holes 6 are formed, as shown in FIGS. 4A and 4B.

At this time, a portion of photoresist film 5 is supplied on top of thin film portion 3a located between patterned holes 4 and, therefore, at least thin film portion 3a can be left at the time of the etching of insulating film 2. Thereby, as shown in FIGS. 4A and 4B, insulating film 2 beneath thin film portion 3a can be prevented from being etched so that contact holes 6 are be prevented from becoming connected to each other.

After that, conductive films or the like are filled in within contact holes 6 and, moreover, wires and the like are formed over insulating film 2 so as to form the semiconductor device of the first embodiment.

(Second Embodiment)

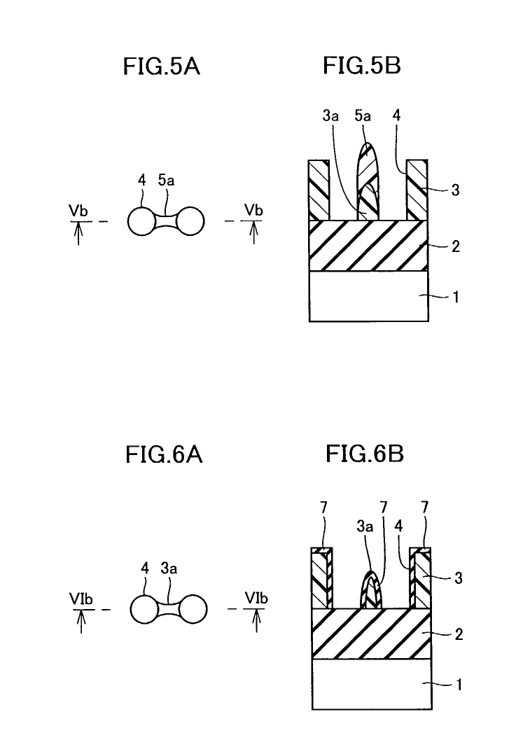

Next, the second embodiment of the present invention will be described. FIGS. 5A and 5B are a plan view and a cross sectional view showing a mask pattern formation process characteristic of the second embodiment.

A mask film is supplied only on top of a thin film portion of the mask pattern formed in the first photomechanical process so as to increase the thickness of this thin film portion in the second embodiment. In this case, the same effects as in the first embodiment can be obtained.

First, a photoresist pattern is formed by a photoresist film 3, as shown in FIGS. 5A and 5B, by undergoing the same process as in the first embodiment. At this time, a thin film portion 3a is formed between patterned holes 4. Here, either a positive-type photoresist or a negative-type photoresist may be utilized as photoresist film 3.

Next, thin film portion 3a is detected. The location of thin film portion 3a can be predicted by means of, for example, an optical simulation using the above described photoresist pattern. In addition, the above described photoresist pattern is used to actually etch insulating film 2 so that recesses other than the patterned holes created in insulating film 2 can be detected through microscopic observation of the substrate from above, such as by using a SEM (Scanning Electron Microscope).

Next, a photoresist film 5 is applied to the pattern of photoresist film 3, and then photoresist film 5 is exposed in the same manner as in the case of FIG. 2. In the case that photoresist film 5 is a positive-type photoresist, the above described exposure is carried out using a photomask having a light blocking film in the location of the above described thin film portion 3a or in the locations of the recesses so as to allow light to be irradiated on the portions other than the location of thin film portion 3a or the locations of the recesses. On the other hand, in the case that photoresist film 5 is a negative-type photoresist, the above described exposure is carried out so that light is irradiated on the portions corresponding to the location of the above described thin film portion 3a or to the locations of the recesses using a photomask having a light blocking film in the portions other than the location of thin film portion 3a or the locations of the recesses.

By carrying out development after this exposure, photoresist film 5 can be left only on top of thin film portion 3a, as shown in FIGS. 5A and 5B. The example of FIGS. 5A and 5B indicates a case wherein a thin film portion 5a (second mask pattern) is formed on top of thin film portion 3a. In this case, also, the thickness of thin film portion 3a can be increased.

Here, in the case that a negative-type photoresist is utilized as photoresist film 5, which is applied in the second photomechanical process, exposure is not carried out on hole pattern 4, which is formed in the first photomechanical process, and therefore, this hole pattern 4 remains unaffected. That is to say, the second photomechanical process can prevent the fluctuation of the form or dimensions of hole pattern 4. Accordingly, the below described contact hole 6 having a high precision can be formed.

Next, insulating film 2 is etched using the photoresist pattern of photoresist film 3 and the photoresist pattern of photoresist film 5 as a mask, thereby contact holes 6 having the same form as in the case shown in FIGS. 4A and 4B can be formed in insulating film 2. The same process as in the first embodiment is carried out hereafter so that a semiconductor device of the second embodiment is formed.

(Third Embodiment)

Next, the third embodiment of the present invention will be described. FIGS. 6A and 6B are a plan view and a cross sectional view showing a mask pattern formation process characteristic of the third embodiment.

In the above described first and second embodiments, a photoresist film is again formed after the formation of the photoresist pattern. In this case, mixing between the photoresist film of the first layer and the photoresist film of the second layer is caused, in some cases, due to the material utilized. Here, mixing indicates a phenomenon wherein the photoresist liquid applied at the time of the second photomechanical process dissolves the photoresist pattern of the first layer so as to cause the mixing of these photoresists.

Therefore, a process is carried out for hardening the surface of the photoresist pattern of the first layer after the first photomechanical process. Thereby, the photoresist pattern of the first layer can be reinforced and, at the same time, the above described mixing can be prevented. As a result, collapse of the layered structure of the two photoresist patterns can be prevented.

In the third embodiment, first, the same process as in the first embodiment is carried out so that the photoresist pattern of the first layer in photoresist film 3 is formed, as shown in FIGS. 6A and 6B.

Then, a process is carried out on this photoresist pattern so as to harden the surface thereof. A DUV (Deep Ultraviolet) curing process can be cited as this surface hardening process. In the case of a photoresist for KrF, for example, a curing process using a wavelength of 222 nm is carried out for approximately 90 seconds.

By carrying out the above described curing process, a crosslinking reaction occurs in the surface of patterned photoresist film 3 (first mask pattern) so that a hardened layer 7 can be formed on the surface of patterned photoresist film 3.

Next, a photoresist film 5 is applied to hardened layer 7 so as to cover this hardened layer 7 in the same manner as in the first embodiment. At this time, the existence of hardened layer 7 can prevent mixing between photoresist film 3 and photoresist film 5.

After photoresist film 5 is applied in this manner, the same process as in the first and second embodiments is carried out so as to form a semiconductor device of the third embodiment.

(Fourth Embodiment)

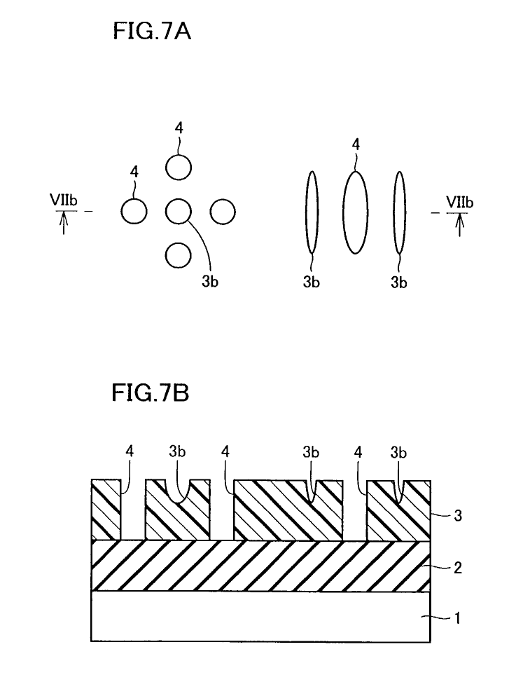

Next, the fourth embodiment of the present invention will be described. FIGS. 7A and 7B to FIGS. 10A and 10B are plan views and cross sectional views showing the respective manufacturing steps of a semiconductor device using a mask pattern formation method according to the fourth embodiment.

First, a photoresist film 3 is applied to an insulating film 2 according to the same process as in the first embodiment. This photoresist film 3 is exposed using a halftone phase shift mask having a predetermined pattern.

After this, photoresist film 3 can be patterned as shown in FIGS. 7A and 7B through development. At this time, recesses 3b, referred to as dimples, or the like, are formed at the center portion of the region wherein patterned holes 4 are concentrated or in the vicinity of a patterned hole 4, of which the area of the opening is large. The location of such a dimple 3b is detected by the same technique used in the second embodiment.

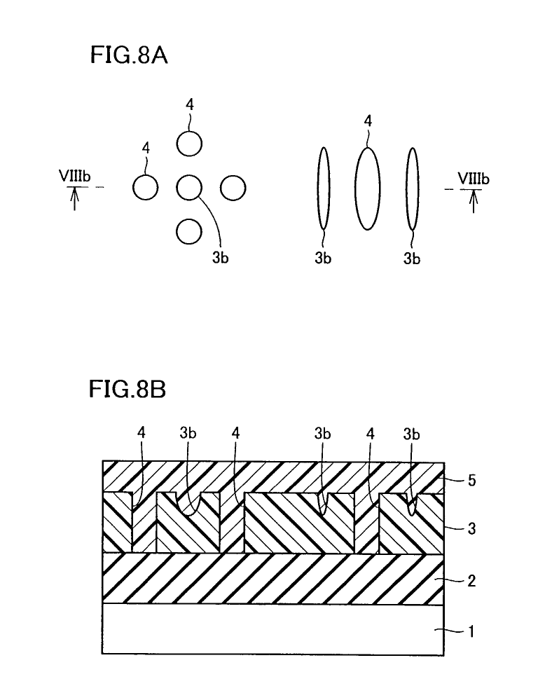

Next, a photoresist film 5 is formed so as to cover the patterned photoresist film 3 (first mask pattern), as shown in FIGS. 8A and 8B. In the case that photoresist film 5 is a positive-type photoresist, a photomask having a light blocking film at the above described location of recess 3b, so that light is irradiated to locations other than the location of recess 3b, is used so as to carry out an exposure. On the other hand, in the case that photoresist film 5 is a negative-type photoresist, a photomask having a light blocking film at locations other than the location of recess 3b so that the portion corresponding to the location of recess 3b is irradiated with light is used so as to carry out an exposure.

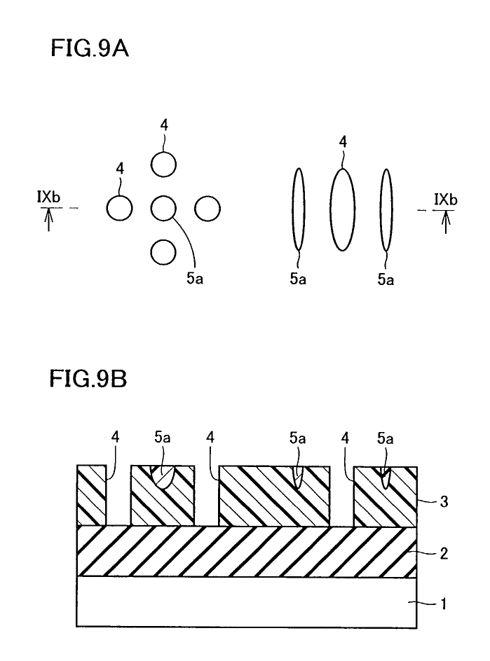

A pattern (second mask pattern) can be formed by photoresist film 5 through development after this exposure and, at the same time, photoresist film 5 can be left only on top of recess 3b, as shown in FIGS. 9A and 9B. Thereby, the thickness of photoresist film 3 in a portion wherein recess 3b exists can be increased.

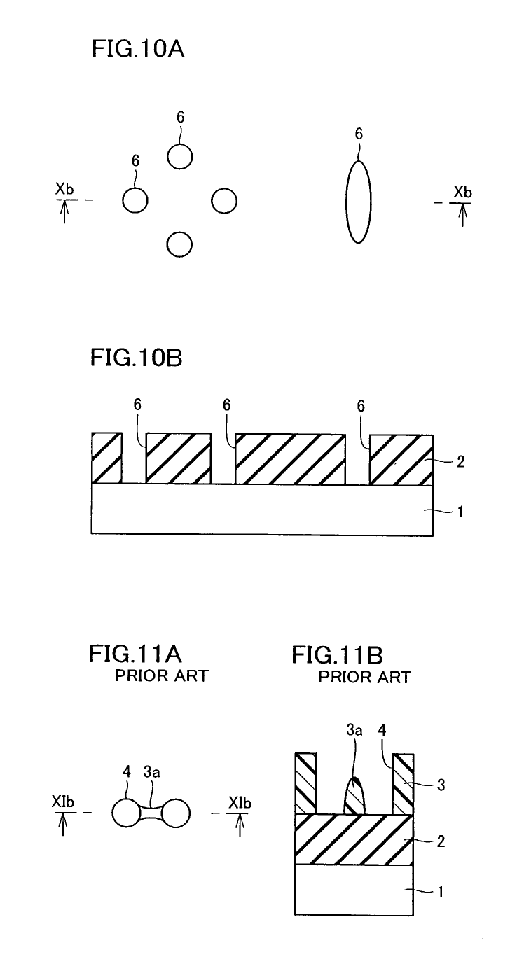

Next, insulating film 2 is etched using the photoresist pattern shown in FIGS. 9A and 9B as a mask. Thereby, contact holes 6 can be formed, as shown in FIGS. 10A and 10B.

At this time, the thickness of photoresist film 3 in the portion where recess 3b exists can be increased by means of photoresist film 5 and, therefore, a recess, caused by the above described existence of recess 3b, can be prevented from being formed in the surface of insulating film 2. The same process as in the first embodiment is carried out hereafter so that a semiconductor device according to the fourth embodiment is formed.

Though the embodiment of the present invention is described above, it is foreseen from the beginning that the characteristics of the respective embodiments are appropriately combined. In addition, though a case wherein a mask pattern formation method of the present invention is applied in a manufacturing method for a semiconductor device is described in the above embodiments, a mask pattern formation method of the present invention is applicable in a device other than a semiconductor device, such as a liquid crystal display device.

As described above, the thickness of a thin film portion in a first mask pattern can be increased according to the present invention and, therefore, a desired process can be carried out on an underlying portion using first and second mask patterns. For example, in the case that a plurality of holes is formed in proximity to each other in a semiconductor substrate or in a film on a semiconductor substrate using first and second mask patterns, the state wherein the holes are connected to each other can be prevented. Accordingly, a semiconductor device having a high reliability can be manufactured. In addition, miniaturization of the pattern and the formation of a pattern of which the area of the opening is large, such as of rectangular holes, become possible increasing the freedom of pattern design.

In the case that a second mask pattern having of substantially the same form as the first mask pattern is formed over this first mask pattern, the second mask film can be left on top of the thin film portion of the first mask pattern. Thereby, the thickness of the thin film portion of the first mask pattern can be increased so as to obtain the above described effects.

In the case that first and second mask films are photoresist films, the second mask pattern is formed using the same photomask as the photomask for the formation of the first mask pattern, thereby the thickness of the thin film portion of the first mask pattern can be increased. In this case, also, the above described effects are obtained.

In addition, in the case that the second mask film is patterned so that the second mask film is left only on top of the thin film portion of the first mask pattern, the thickness of the thin film portion of the first mask pattern can be increased in the same manner so that the above described effects are obtained.

In this case, by utilizing a positive-type photoresist film as the first mask film and a negative-type photoresist film as the second mask film, the second mask pattern can be formed without exposing the patterned portion (hole portions in the case that a hole pattern is formed) in the first mask pattern. Accordingly, the resulting patterned portions of the first mask pattern can be prevented from becoming deformed and fluctuation in dimensions of the patterned portions can be prevented from occurring by means of the process for the formation of the second mask pattern.

In the case that a hardened layer is formed on the surface of the first mask pattern after the patterning of the first mask film, mixing between the first and second mask films can be prevented and, furthermore, the first mask film can be reinforced. Thereby, even in the case that the second mask pattern is formed over the first mask pattern, the state can be avoided wherein the layered structure of the first and second mask patterns are collapsed.

The present invention is useful at the time when a semiconductor substrate, a film formed on a semiconductor substrate or the like is processed. In particular, the present invention is useful in the case that a photoresist film is patterned in a predetermined form by means of a photomechanical process so as to form a mask film, and then a semiconductor substrate, or a variety of films formed on a semiconductor substrate, are processed (etched, or the like) using this mask.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A device manufacturing method comprising the steps of:
forming a first mask film on an underlying portion;
forming a first mask pattern including a thin film portion by patterning said first mask film;
forming a second mask film on the first mask pattern so as to cover said thin film portion;
forming a second mask pattern by patterning said second mask film and leaving a portion of said second mask film on said thin film portion; and
processing said underlying portion using said first and second mask patterns.

2. The device manufacturing method according to claim 1, wherein
said step of patterning the second mask film includes the step of forming said second mask pattern so that the second mask pattern becomes a pattern of the same form as of said first mask pattern.

3. The device manufacturing method according to claim 2, wherein
said first and second mask films are photoresist films, and
said second mask pattern is formed using the same photomask as a photomask for the formation of said first mask pattern.

4. The device manufacturing method according to claim 1, wherein
said step of patterning the second mask film includes the step of patterning said second mask film so as to leave said second mask film on only the thin film portion of said first mask pattern.

5. The device manufacturing method according to claim 4, wherein
said first mask film is a positive-type photoresist film, and
said second mask film is a negative-type photoresist film.

6. The device manufacturing method according to claim 1, comprising the step of
forming a hardened layer on a surface of said first mask pattern after said first mask film is patterned.
